(19) United States
(12) Patent Application Publication
(10) Pub. No.: US 2016/0284634 A1
(43) Pub. Date: Sep. 29, 2016

(54) SEMICONDUCTOR TRANSISTOR PACKAGE STRUCTURE

(71) Applicant: Chung Hsing TZU, Taipei (TW)

(72) Inventor: Chung Hsing TZU, Taipei (TW)

(21) Appl. No.: 14/672,184

(22) Filed: Mar. 29, 2015

(51) Int. Cl. H01L 23/495

(52) U.S. Cl. CPC H01L 23/49582; H01L 23/4952; H01L 23/49503

(57) ABSTRACT

A semiconductor transistor package structure is disclosed and is applicable for the transistors, such as IGBT or MOSFET. The structure is mainly used for electrically connecting with the chip and the lead frame or circuit board. Before soldering, a second layer is electroplated thereon to improve the drawbacks of the metal connecting wire easy to be oxidized and bad electrical connection. Besides saving the process time and enhancing yield rate, the life time of the transistors.

### FIELD OF THE INVENTION

The present invention relates to a semiconductor transistor, and more particularly to a semiconductor transistor package structure. It is applicable for the transistors, such as IGBT or MOSFET. The structure is mainly used for electrically connecting with the chip and the lead frame or circuit board. Before soldering, a second layer is electroplated thereon to improve the drawbacks of the metal connecting wire easy to be oxidized and bad electrical connection. Besides saving the process time and enhancing yield rate, the life time of the transistors.

Please refer to FIG. 1, the conventional semiconductor transistor package structure may mainly include a lead frame or circuit board 3. A connecting bonding pad 31 is arranged in the lead frame or circuit board 31 for providing the second end 52 of a wire 3 to be electrically connected. A chip 1 may be fastened on the lead frame or circuit board 3 with an adhesive 2. A chip bonding pad 11 may be arranged on the chip 1. A gold ball bump 4 may be soldered on the chip bonding pad 11. The first end 51 of the wire 5 may be soldered with the gold ball bump 4 to electrically connecting with the chip 1 and the lead frame or circuit board 3. To cost down and attend to rigidity, the wire 5 may be only made from copper. However, copper is rigid and the form is different. Copper is hard to bond with gold, so the wire 5 is hard to bond with the gold ball bump 4. Furthermore, copper is easy to be oxidized, the electrical connection may be influenced while oxidizing. It is also easy to shorten the life time of the semiconductor transistor and reduce yield rate.

An objective of this invention is providing a semiconductor transistor package structure. The structure is mainly used for electrically connecting with the chip and the lead frame or circuit board. Before soldering, a second layer is electroplated thereon to improve the drawbacks of the metal connecting wire easy to be oxidized and bad electrical connection. Besides saving the process time and enhancing yield rate, the life time of the transistors.

To achieve above objectives, a semiconductor transistor package structure is provided. The structure may comprise a lead frame or circuit board, having a connecting bonding pad embedded therein for providing a second end of a metal connecting wire to be soldered and electrically connected with; a chip, fastened on the lead frame or circuit board with adhesive, a chip bonding pad is arranged at an upper surface of the chip for providing a first end of the metal connecting wire to be soldered directly and electrically connected with; and the metal connecting wire, having an inner layer portion and an outer layer portion, the first end of the metal connecting wire is electrically connected with the chip bonding pad of the chip, and the second of the metal connecting wire is electrically connected with the lead frame or circuit board to achieve the electrical connection.

In some embodiment a gold ball bump is formed on the chip bonding pad for electrically connecting with the first end of the metal connecting wire.

In some embodiment the inner layer portion of the metal connecting wire is made from copper.

In some embodiment the outer layer portion of the metal connecting wire is made from materials with oxidation resistance. The materials at least include gold, silver, and palladium.

Further features and advantages of the present invention will become apparent to those of skill in the art in view of the detailed description of preferred embodiments which follows, when considered together with the attached drawings and claims.

### BRIEF DESCRIPTION OF THE DRAWINGS

All the objects, advantages, and novel features of the invention will become more apparent from the following detailed descriptions when taken in conjunction with the accompanying drawings.

FIG. 1 is a side view of a conventional semiconductor transistor package structure.

FIG. 2 is a side view of a semiconductor transistor package structure according to this present invention.

Referring now to the drawings where like characteristics and features among the various figures are denoted by like reference characters.

FIG. 2 is a side view of a semiconductor transistor package structure according to this present invention.

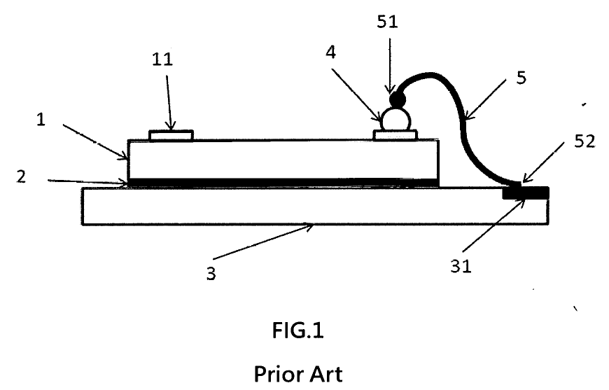

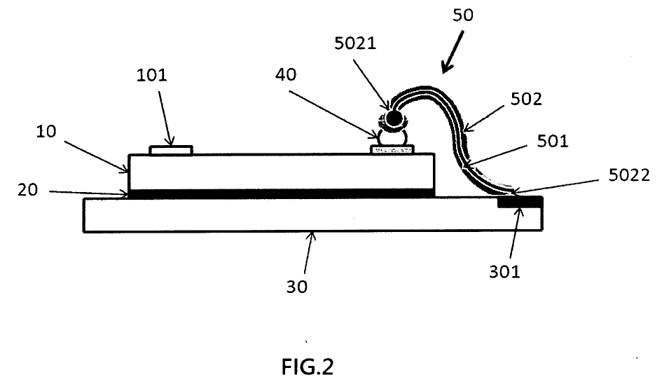

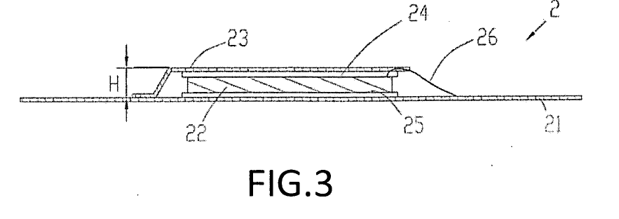

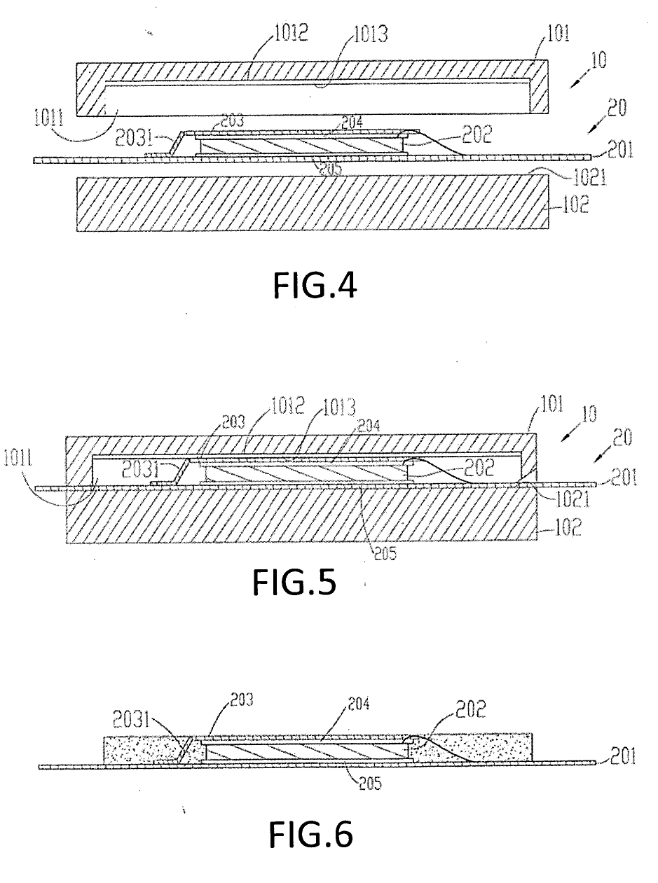

Please refer to FIG. 2, the semiconductor transistor package structure of this invention may comprise a lead frame or circuit board 30, a chip 10, and a metal connecting wire 50.

A connecting bonding pad 301 may be embedded in the lead frame or circuit board 30 for providing a second end 5022 of the metal connecting wire 50 to be soldered and electrically connected with and make the signals of the chip 10 be transmitted to the lead frame or circuit board 30.

An adhesive 20 may be coated on the lead frame or circuit board 30 and the chip 10 may be arranged on the adhesive 20. It may make the chip 10 be fastened on the lead frame or circuit board 30 by the processes of backing, cooling, and setting.

The chip bonding pad 101 may be arranged at an upper surface of the chip 10 for providing a first end 5021 of the metal connecting wire 50 to be soldered directly and electrically connected with. In addition, a gold ball bump 40 may be firstly formed on the chip bonding pad 101 and then the gold ball bump 40 may be electrically connecting with the first end 5021 of the metal connecting wire 50 to achieve better electrical connection.

The metal connecting wire 50 may have an inner layer portion 501 and an outer layer portion 502. The inner layer portion 501 is mainly made from copper. The copper is a metal with high oxidation. The electrical connection of copper may be reduced while being oxidized. In order to improve the property of high oxidation of the metal connecting wire 50 made from copper, before the first end 5021 and the second end 5022 of the metal connecting wire 50 are respective soldered with the chip bonding pad 101 or gold ball bump 40 of the chip 10 and the connecting bonding pad 301 of the lead frame or circuit board 30, the outer layer portion 502 may be coated around the inner layer portion 501 of the metal connecting wire 50 with electroplating. The outer layer portion 502 of the metal connecting wire 50 may be made from materials with oxidation resistance. The materials at least include gold, silver, and palladium.

Therefore, the outer layer portion 502 may be coated around the inner layer portion 501 of the metal connecting wire 50 with electroplating first, and then the chip 10 may be fastened on the lead fame or circuit board 30 with the adhesive 20. Further, the gold ball bump 40 may be formed on the chip bonding pad 101 of the chip 10. Finally, the first end 5021 of the metal connecting wire 50 with the inner layer portion 501 and the outer layer portion 502 electroplated with each other may be soldered on the gold ball bump 40 with ultrasonic soldering, and the second end 5022 thereof may be soldered on the connecting bonding pad 301 of the lead frame or circuit board 50 with ultrasonic soldering after cutting the metal connecting wire 50 with a preset length. It can finish the electrical connecting of the chip 10 and the lead frame or circuit board 30 and the process of the chipset. Later, the chipset may be packaged.

In conclusion, compared to the prior art, besides improving the drawbacks of the metal connecting wire 50 easy to be oxidized and bad electrical connection, the semiconductor transistor package structure of this invention may effectively improve the process time while the metal connecting wire 50 is processing the ultrasonic soldering and prevent no signal from bad electrical connection, due to the materials of the metal connecting wire 50. Therefore, the yield rate for producing the chipset may be enhanced, the process time may be reduced, and the production may be increased.

1. A semiconductor transistor package structure, comprising:
a lead frame or circuit board, having a connecting bonding pad embedded therein for providing a second end of a metal connecting wire to be soldered and electrically connected with;
a chip, fastened on the lead frame or circuit board with adhesive, a chip bonding pad is arranged at an upper surface of the chip for providing a first end of the metal connecting wire to be soldered directly and electrically connected with; and
the metal connecting wire, having an inner layer portion and an outer layer portion, the first end of the metal connecting wire is electrically connected with the chip bonding pad of the chip, and the second end of the metal connecting wire is electrically connected with the lead frame or circuit board to achieve the electrical connection.

2. (canceled)

3. (canceled)

4. (canceled)

5. (canceled)
